(19) United States
(12) Patent Application Publication
(10) Pub. No.: US 2009/0140382 A1
(43) Pub. Date: Jun. 4, 2009

(54) ELECTRIC FUSE DEVICE MADE OF POLYSILICON SILICIDE

(76) Inventors: Wen-Yu Gao, Shanghai (CN); Min-Xia Wei, Shanghai (CN); Ray Li, Shanghai (CN); Ching-Dong Wang, Shanghai (CN)

Correspondence Address: SINORICA, LLC, 528 FALLSGROVE DRIVE, ROCKVILLE, MD, 20850, US

(21) Appl. No.: 12/277,752

(22) Filed: Nov. 25, 2008

(30) Foreign Application Priority Data
Nov. 30, 2007 (CN) 200710171606.1

(51) Int. Cl. H01L 23/525

(52) U.S. Cl. 257/529; 257/E23.149

(57) ABSTRACT

A polysilicon silicide electric fuse device, comprising: a substrate; a semiconductor material layer disposed on said substrate, said semiconductor material layer includes lead-out areas of the same doping type at both ends, and an intermediate area of non-doping or having dopant concentration lower than those of said lead-out areas at both ends; and one or more burn-out areas is/are provided in said intermediate area; and a metal silicide layer is provided on said semiconductor material layer. Through the application of said polysilicon silicide electric fuse device, the burning out of said fuse device is thus controlled to within said intermediate area of no doping or light doping, hereby increasing the mean value and reducing distribution area of electrical resistance after burning out of a fuse, and alleviating the overheating of surrounding areas as caused by a current during the burning out of a fuse.

### BACKGROUND OF THE INVENTION

1. Field of the Invention

The present invention relates to a an electric fuse device used in a semiconductor integrated circuit, and in particular to a new kind of electric fuse structure made of polysilicon and metal silicide.

2. The Prior Arts

In general, an electric fuse is a device that is utilized frequently in a semiconductor integrated circuit. It is essentially a wiring of low electrical resistance, and when it is applied a high voltage and burns out, its electrical resistance tends to become exceedingly large, thus being equivalent to a disconnection of a wiring. Usually, there are mainly two applications for this kind of electric fuse. The first application is that, such an electric fuse is arranged to be connected to a redundant circuit under test, and when it is detected there is a defective element or component in a circuit while conducting a circuit testing, the electric fuse connected to a defective element will be burned out through applying a high voltage, then selecting and switching to a redundancy element having the same functions for replacement. The other application of this kind of electric fuse is the manufacturing of integrated circuits through programming. Namely, firstly, programmed circuits and arrays of elements contained therein are pre-arranged and produced on a chip through programming. Then, control data are input from outside to burn out fuses according to a computer program, hereby obtaining a desired circuit. An exemplary example of this application is the manufacturing of a Programmable Read Only Memory (PROM). Wherein, the writing in of information “1” is achieved through burning out the related fuse into an “open circuit” state, and the information of “0” is maintained by keeping a fuse in a connected and “closed circuit” state.

In this respect, referring to FIGS. 1-3 for a top view and cross-section views of an electric fuse device made of polysilicon silicide according to a first prior art (application No. 96198416.3 PRC). As shown in FIGS. 1-3, a bottleneck shaped polysilicon layer 02 is formed on a dielectric such as silicon dioxide 01. Wherein, the polysilicon layer can be doped with an N-type dopant or a P-type dopant or without dopant. A metal silicide layer 03 can be made by a conventional silicide producing technology, and contact holes 04 are formed in lead-out areas on both sides of a metal silicide layer 03 to lead out two ends of a fuse. In the structure mentioned above, the electrical resistance of a metal silicide block is comparatively small, and when high voltage pulses are applied to both ends 04a and 04b of contact holes of a polysilicon silicide electric fuse devices, then a large instantaneous current will flow through a burn-out area (namely, a bottleneck portion) of the metal silicide layer 03, thus burning out the silicide to form a structure of a polysilicon silicide electric fuse device as shown in FIG. 3. Meanwhile, the heat generated by this instantaneous large current will result in the re-crystallization of polysilicon and the redistribution of impurity under the burn-out area, as such significantly increasing the electrical resistance at both ends 04a and 04b of a fuse.

With the rapid progress and development of the technology of integrated circuit, the sizes of devices are required to reduce continuously, thus the fuse structure mentioned above has the following shortcomings: firstly, there tend to have silicide fuse residues after the fuse burn-out as caused by the application of electrical voltages, or the re-crystallization of polysilicon is liable to be unstable, hereby resulting in the enlargement of electrical resistance distribution area after burn-out of fuse and the reduction of mean value; secondly, the high heat generated by a current flowing into a fuse will cause the overheating of the adjacent devices on a chip, thereby adversely affecting the stable performance of the devices.

In order to overcome the two major shortcomings mentioned above, referring to FIG. 4 for a second prior art according to an American Patent U.S. Pat. No. 7,227,238A. Wherein, the polysilicon of a fuse is doped in three separate and different sections. As shown in FIG. 4, sections 02a,02b,02c are three sections having different dopings, wherein, section 02a is doped with an N-type (or a P-type) dopant, section 02c is doped with a P-type (or an N-type) dopant opposite to that of section 02a, and section 2b can be doped with no-dopant, N-type dopant, P-type dopant, or an N-type dopant and a P-type dopant in combination. The above three sections are all polysilicons deposited in a same layer, and the dopings are realized by means of ion implantation. In addition, the implantation mask used in dopings can be utilized in an N+ implanatation, and/or a P+ implantation, and/or an N-type Lightly-Doped-Drain (NLDD) implantation, and/or a P-type Lightly-Doped-Drain (PLDD) implantation in producing a CMOS integrated circuit, as such a polysilicon fuse can be realized through pattern design without increasing any process steps and chip area. However, in the process of manufacturing mentioned above, two layers of ion implanatation masks are required, and the alignment error of these two layers of masks will affect the sizes of the three polysilicon sections significantly, hereby adversely affecting the uniformity of electrical resistance after the burning out of a fuse.

### SUMMARY OF THE INVENTION

In view of the problems and shortcomings of the prior art, the present invention provides an electric fuse device made of polysilicon silicide, that can be used in a semiconductor integrated circuit.

A major objective of the present invention is to provide a polysilicon silicide electric fuse device capable of controlling the burn-out of fuse within an intermediate burn-out area.

To achieve the above-mentioned objective, the present invention provides a polysilicon silicide electric fuse device, including:
a substrate; a semiconductor material layer disposed on the substrate, the semiconductor material layer includes lead-out areas of the same dopant type at both ends, and an intermediate area of non-doping or having dopant concentration lower than those of the lead-out areas at both ends; and one or more burn-out areas is /are provided in the intermediate area; and a metal silicide layer is provided on the semiconductor material layer.

According to an aspect of the present invention, a dielectric layer is further provided on the metal silicide layer, and one or a plurality of contact holes penetrating through to the metal silicide layer is or are provided at the lead-out areas on both sides of the dielectric layer.

According to another aspect of the present invention, the contact holes are located at one side of the lead-out area that is further away from the burn-out area.

According to another aspect of the present invention, the semiconductor material layer is made of one of polysilicon, amorphous silicon, or germanium-silicon alloy.

According to yet another aspect of the present invention, the width of a side near the contact holes of at least a lead-out area is greater than the width of a side near the burn-out area.

According to still another aspect of the present invention, the burn-out area coincides with the intermediate area.

According to another aspect of the present invention, at least a lead-out area includes a thin and long lead-out end, such that the lead-out area is adjacent to the intermediate area through the lead-out end.

According to yet another aspect of the present invention, the lead-out end is of a step shape.

According to still another aspect of the present invention, the width of a burn-out area is smaller than the maximum width of the intermediate area.

According to a further aspect of the present invention, the burn-out area is formed by a plurality of long-strip structures connected in series.

According to yet another aspect of the present invention, the burn-out area is formed by one or more bent or crooked structures connected in series.

In the present invention, a polysilicon silicide electric fuse device is provided, that is realized through a structure of three sections and having two types of dopings. The lead-out areas at two ends are of the same type of doping (P type or N type), a burn-out area in the middle is a non-dope area or lightly-doped area. As such, the doping of lead-out areas at two ends and the non-doping of a burn-out area are realized through ion implantation by using a layer of mask, or alternatively, the doping of lead-out areas at two ends and the light-doping of a burn-out area can be realized through ion implantation by using two layers of masks. In addition, the mask utilized in the process mentioned above can also be utilized in ion implantation in the manufacturing of CMOS integrated circuit. Therefore, the advantages and benefits of the above-mentioned structures are that, the burning-out of fuse can be controlled within a non-doped or lightly-doped intermediate area, such that after a burn-out, the electrical resistance mean value is increased and the electrical resistance distribution area is reduced, thus alleviating the overheating of surrounding areas caused by a current during fuse burn-out.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a top view of a polysilicon silicide electric fuse device according to the first prior art;

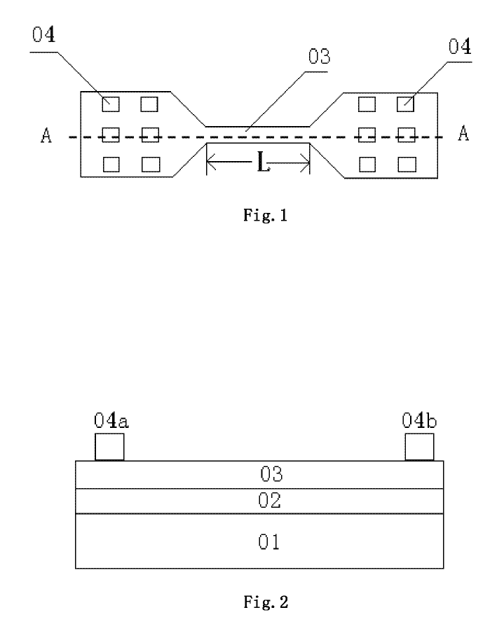

FIG. 2 is a cross section view along an A-A line of a polysilicon silicide electric fuse device before burning out of fuse according to the first prior art;

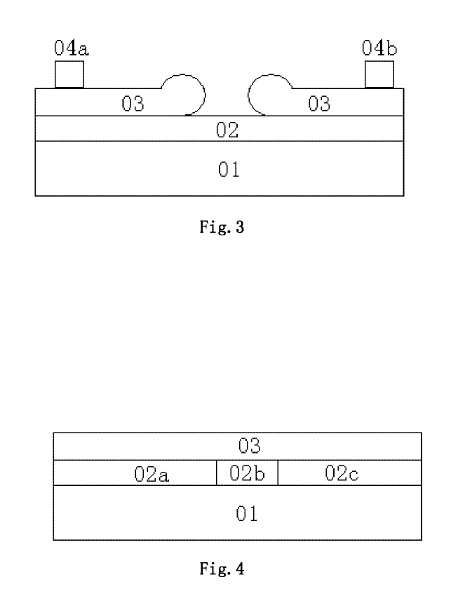

FIG. 3 is a cross section view along an A-A line of a polysilicon silicide electric fuse device after burning out of fuse according to the first prior art;

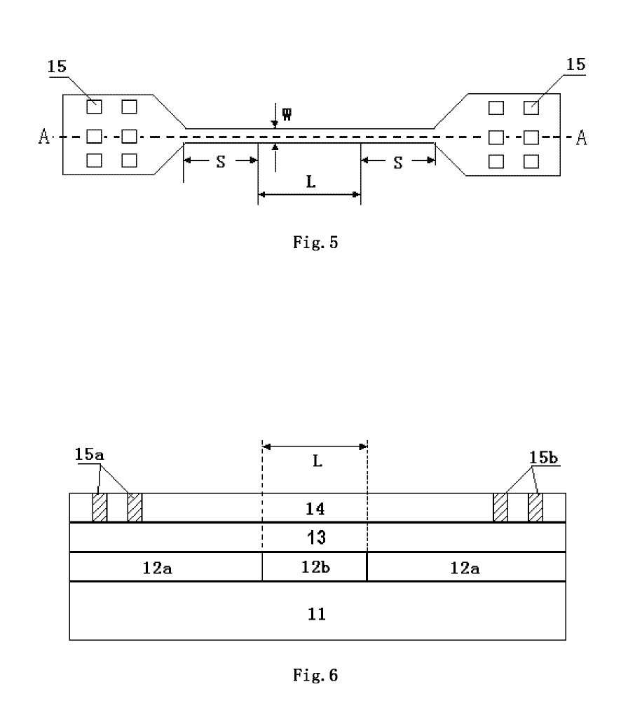

FIG. 4 is a schematic diagram of polysilicon fuse structure having three kinds of dopings according to the second prior art;

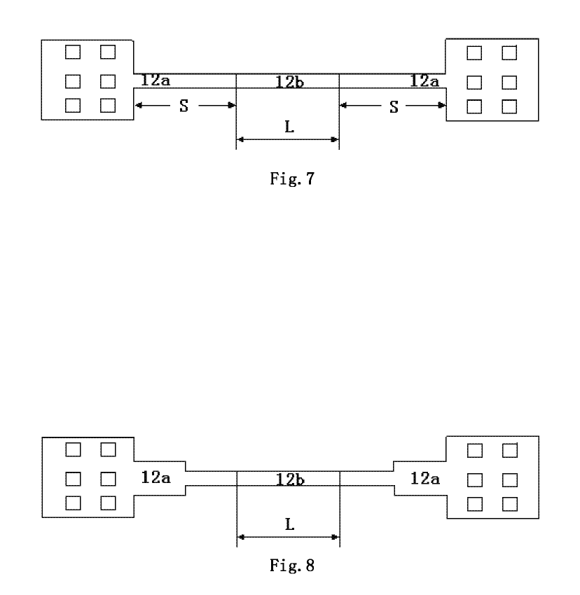

FIG. 5 is a schematic diagram of a polysilicon silicide electric fuse device according to an embodiment of the present invention;

FIG. 6 is a cross section view along an A-A line of a polysilicon silicide electric fuse device as shown in FIG. 5 according to an embodiment of the present invention;

FIGS. 7 to 12 are schematic diagrams of polysilicon silicide electric fuse devices according to various embodiments of the present invention; and

FIGS. 13 to 16 are schematic diagrams of polysilicon silicide electric fuse devices according to an embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

The present invention relates to a an electric fuse device used in a semiconductor integrated circuit, and in particular to a new kind of electric fuse structure made of polysilicon and metal silicide.

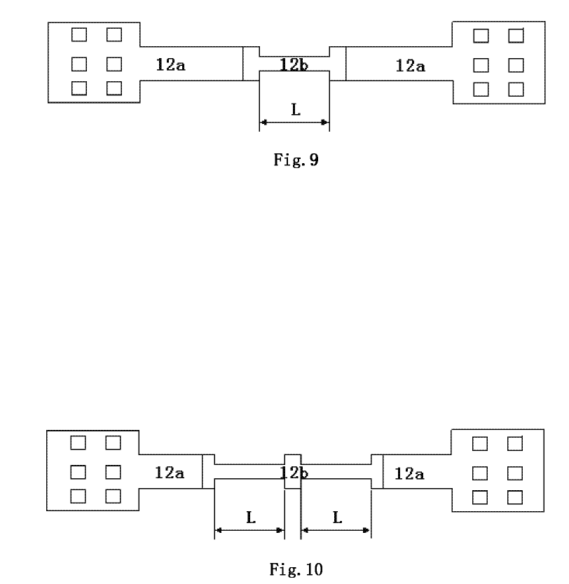

Referring to FIGS. 5 & 6 for a detailed description of a polysilicon silicide electric fuse device of the present invention, including: a substrate 11; a semiconductor material layer 12 disposed on the substrate 11, the semiconductor material layer 12 includes lead-out areas 12a of the same dopant type at both ends, and an intermediate area 12b of no doping or having dopant concentration lower than those of lead-out areas at both ends; and one or more burn-out areas L provided in the intermediate area 12b; and a metal silicide layer 13 provided on the semiconductor material layer 12.

In the structure mentioned above, a dielectric layer 14 is further provided on the metal silicide layer 13, and one or a plurality of contact holes 15 penetrating through to the metal silicide layer 13 is/are provided at the lead-out areas 12a on both ends of the dielectric layer 14.

In the structure mentioned above, the semiconductor material layer 12 is made of one of polysilicon, amorphous silicon, or germanium-silicon alloy.

In the structure mentioned above, the contact holes 15 are located at one side of the lead-out area 12a further away from the burn-out area L.

In the structure mentioned above, the width of a side near the contact holes 15 of at least a lead-out area 12a is greater than the width of a side near a burn-out area L.

In the structure mentioned above, in the lead-out areas 12a, the widths of the two sides near the contact holes 15 of burn-out areas 12a are greater than the widths of the sides near the burn-out area L.

In the structure mentioned above, the burn-out area L coincides with the intermediate area 12b.

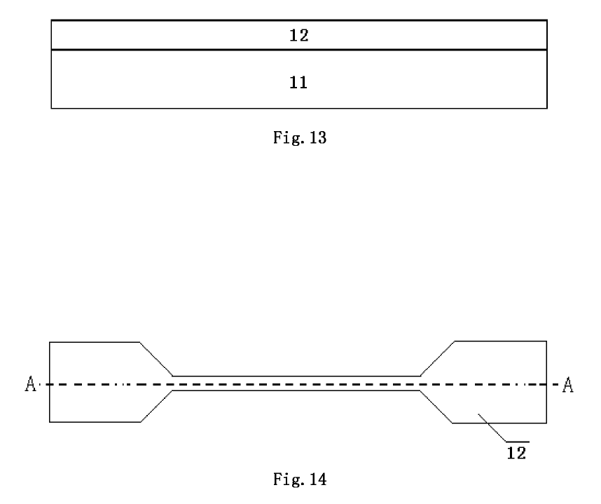

In the structure mentioned above, at least one lead-out area 12a includes a thin and long lead-out end S, such that the lead-out area 12a is adjacent to an intermediate area 12b through the lead-out end S, as shown in FIGS. 7 & 8.

In the structure mentioned above, the lead-out end S is of a step shape, as shown in FIG. 8.

In the structure mentioned above, the width W of a burn-out area L is less than the maximum width of the intermediate area, as shown in FIGS. 9 & 10.

In the structure mentioned above, the burn-out area L is formed by a plurality of long-strip structures connected in series. As shown in FIG. 10, the burn-out area L consists of two long-strip structures connected in series.

In the structure mentioned above, the burn-out area is formed by one or more bent or crooked structures connected in series. As shown in FIGS. 11 & 12, the burn-out area is a crooked structure.

In the present invention, a polysilicon silicide electric fuse device is provided, and that is produced and realized by making use of a standard CMOS manufacturing technology. In the following, a method of manufacturing such a fuse device will be described in conjunction with the attached drawings.

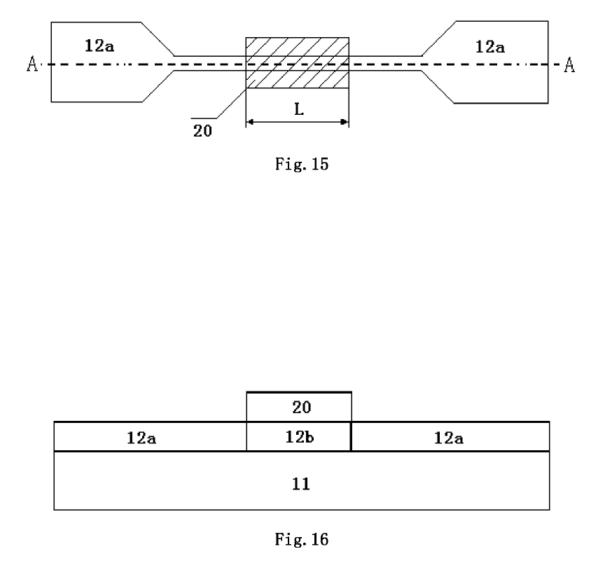

Firstly, referring to FIG. 13 for a schematic diagram of a step in producing a polysilicon silicide electric fuse device according to an embodiment of the present invention. As shown in FIG. 13, firstly, depositing a non-doped polysilicon 12 used for a gate electrode on a layer of silicon dioxide 11, which is itself disposed on a Shallow Trench Isolation (STI) area or a Field Oxide layer; then selectively etching a structure thus obtained into a structure as shown in FIG. 14.

Next, referring to FIGS. 15 & 16 for a schematic diagram of a polysilicon silicide electric fuse device according to an embodiment of the present invention. As shown in FIGS. 15 & 16, firstly, applying a photoresist 20 on a burn-out area L, performing an N-type or a P-type ion implantation in obtaining polysilicon of lead-out areas 12a after ion implantation, and an intermediate area 12b of a non-doped polysilicon, which is located in the area of a burn-out area L. In the present embodiment, the burn-out area L coincides with the intermediate area 12. In the process mentioned above, the ion implantation can be executed separately, or it can be preformed in conjunction with an ion implantation in producing a CMOS integrated circuit, such as an N+ ion implantation and a P+ ion implantation in forming a source electrode and a drain electrode. The intermediate area 12b may also be lightly doped, at this time the entire fuse device can be applied a lightly doped ion implantation, such as an N type or a P type Lightly-Doped-Drain (LDD) ion implantation used in producing a CMOS integrated circuit. Since the length L of a burn-out area is controlled by a mask used for ion implantation, thus the electrical resistance distribution area can be reduced after burning out of a fuse. Wherein, the impurity used for N doping can be Phosphor or Arsenic, while the impurity used for P doping can be Boron or Indium.

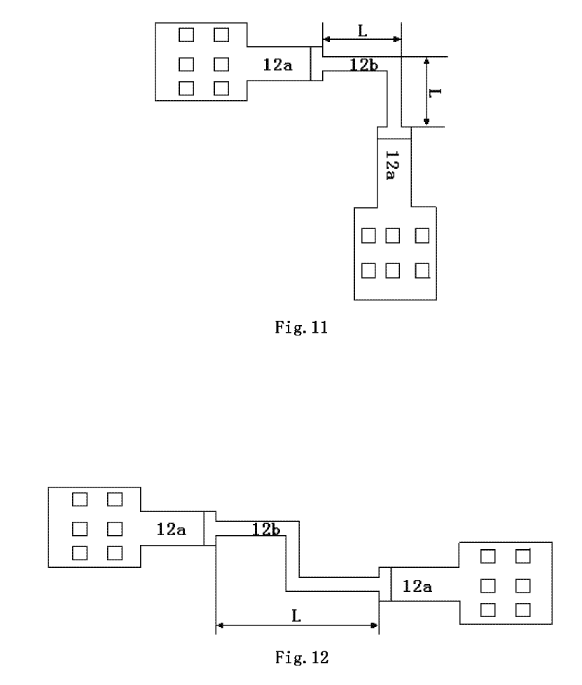

Then, depositing a thin layer of metal, thus forming a metal silicide 13 by means of an ordinary metal silicide self alignment technology, as shown in FIG. 6. The metal silicide 13 mentioned above can be a silicide of Ti, Co, Ni, Ta, and W. The structure of a silicide of W can be obtained directly through depositing and etching. Upon forming a dielectric layer 14 (for example, SiO2), then proceeding with etching of contact holes, thus forming two ports 15a and 15b of the fuse device through ordinary etching technology, as shown in FIGS. 5 and 6.

Lastly, referring to FIGS. 5 & 6. As shown in FIGS. 5 & 6, an intermediate area 12b is a burn-out area, L is the length of the burn-out area 12b, and W is the width of the burn-out area 12b. The burning out of fuse device can be confined into the intermediate area 12b through controlling and regulating the width W and Length L of a burn-out area 12b, the distance S between a burn-out area 12b and silicide of a fuse device lead out end, and dosage of ion implantation of lead out area 12a (including the dosage of a lightly doped intermediate area 12b), so that the electrical resistance distribution area of the resulting fuse after burning out is reduced, and its mean value can be increased.

The above detailed description of the preferred embodiment is intended to describe more clearly the characteristics and spirit of the present invention. However, the preferred embodiments disclosed above is not intended to be any restrictions to the scope of the present invention. Conversely, its purpose is to include the various changes and equivalent arrangements which are within the scope of the appended claims.

What is claimed is:

1. A polysilicon silicide electric fuse device, comprising:
a substrate;
a semiconductor material layer disposed on said substrate, said semiconductor material layer includes lead-out areas of a same doping type at both ends, and an intermediate area of non-doping or having dopant concentration lower than those of said lead-out areas at both ends; and one or more burn-out areas provided in said intermediate area; and
a metal silicide layer provided on said semiconductor material layer.

2. The polysilicon silicide electric fuse device as claimed in claim 1, wherein a dielectric layer is further provided on said metal silicide layer, and one or a plurality of contact holes penetrating through to said metal silicide layer is/are provided at said lead-out areas on both sides of said dielectric layer.

3. The polysilicon silicide electric fuse device as claimed in claim 2, wherein the contact holes are located at one side of said lead-out area further away from said burn-out area.

4. The polysilicon silicide electric fuse device as claimed in claim 1, wherein said semiconductor material layer is made of one of polysilicon, amorphous silicon, or germanium-silicon alloy.

5. The polysilicon silicide electric fuse device as claimed in claim 1, wherein a width of a side near said contact holes in at least said lead-out area is greater than said width of a side near said burn-out area.

6. The polysilicon silicide electric fuse device as claimed in claim 1, wherein said burn-out area coincides with said intermediate area.

7. The polysilicon silicide electric fuse device as claimed in claim 1, wherein at least said lead-out area includes a thin and long lead-out end, such that said lead-out area is adjacent to said intermediate area through said lead-out end.

8. The polysilicon silicide electric fuse device as claimed in claim 7, wherein said lead-out end is of a step shape.

9. The polysilicon silicide electric fuse device as claimed in claim 1, wherein said width of said burn-out area is less than the maximum width of said immediate area.

10. The polysilicon silicide electric fuse device as claimed in claim 1, wherein said burn-out area is formed by a plurality of long-strip structures connected in series.

11. The polysilicon silicide electric fuse device as claimed in claim 1, wherein said burn-out area is formed by one or more bent or crooked structures connected in series.
